(19) United States
(12) Patent Application Publication
(10) Pub. No.: US 2026/0144069 A1
(43) Pub. Date: May 21, 2026

(54) SEMICONDUCTOR PACKAGE

(71) Applicant: Samsung Electronics Co., Ltd., Suwon-si (KR)

(72) Inventors: Seong Yeon PARK, Suwon-si (KR); INKYU PARK, Suwon-si (KR); SEUNG-KWAN RYU, Suwon-si (KR); Wongu LEE, Suwon-si (KR)

(21) Appl. No.: 19/251,612

(22) Filed: Jun. 26, 2025

(30) Foreign Application Priority Data
Nov. 19, 2024 (KR) 10-2024-0165284

(51) Int. Cl. H01L 23/00; H01L 23/06; H01L 23/31; H01L 23/48; H01L 23/538; H01L 25/04

(52) U.S. Cl. CPC H10W 42/121; H10W 20/20; H10W 70/611; H10W 70/65; H10W 74/131; H10W 76/17; H10W 90/00; H10W 90/722; H10W 90/736

(57) ABSTRACT

Provided is a semiconductor package including a substrate, a first semiconductor chip mounted on the substrate, a chip stack disposed on the substrate spaced apart from the first semiconductor chip in a horizontal direction, a molding layer on the substrate surrounding sides of the chip stack and sides of the first semiconductor chip, and a first metal layer disposed on an upper surface of the molding layer, an upper surface of the first semiconductor chip, and an upper surface of the chip stack. The first metal layer includes a shape memory alloy that is configured to reversibly change a shape thereof according to a temperature of the first metal layer.

### CROSS-REFERENCE TO RELATED APPLICATIONS

This U.S. non-provisional patent application claims priority under 35 U.S.C. § 119 of Korean Patent Application No. 10-2024-0165284, filed on Nov. 19, 2024, the entire contents of which are hereby incorporated by reference.

### BACKGROUND

The present disclosure herein relates to a semiconductor package.

With development of the electronics industry, demand for high-performance, high-speed, and miniaturization of an electronic component is increasing. In response to this trend, recent packaging technology is moving in a direction in which a plurality of semiconductor chips are mounted in one package.

In a recent electronic product market, demand of a portable device is dramatically increasing, and thus miniaturization and decreased weight of the electronic components mounted thereon are preferred. In order to realize the miniaturization and the reduced weight of the electronic components, not only is technology that reduces an individual size of the mounted component needed, but also a semiconductor package technology that integrates many individual devices into a single package is required.

### SUMMARY

The present disclosure provides a semiconductor package with improved mechanical characteristics and a method for manufacturing the same.

The present disclosure also provides a semiconductor package with improved stability and a method for manufacturing the same.

The technical benefit of the inventive concept is not limited to the benefits mentioned above, and other technical benefits that are not mentioned may be clearly understood from the description below by those skilled in the art.

An embodiment of the inventive concept provides a semiconductor package including a substrate, a first semiconductor chip mounted on the substrate, a chip stack disposed on the substrate spaced apart from the first semiconductor chip in a horizontal direction, a molding layer on the substrate, the molding layer surrounding sides of the chip stack and sides of the first semiconductor chip, and a first metal layer disposed on an upper surface of the molding layer, an upper surface of the first semiconductor chip, and an upper surface of the chip stack, wherein the first metal layer includes a shape memory alloy that is configured to reversibly change a shape thereof according to a temperature of the first metal layer.

In an embodiment of the inventive concept, a semiconductor package includes a package substrate, an interposer substrate on the package substrate, a first semiconductor chip on the interposer substrate, a molding layer surrounding the first semiconductor chip on the interposer substrate, and a metal layer on an upper surface of the molding layer and on the first semiconductor chip, wherein the metal layer includes a shape memory alloy that is configured to reversibly change between crystalline phases according to a temperature of the metal layer, and the metal layer has a crystalline phase change temperature between 70° C. and 110° C.

In an embodiment of the inventive concept, a method for manufacturing a semiconductor package includes providing an interposer substrate, mounting a first semiconductor chip and a chip stack on an upper surface of the interposer substrate, forming a molding layer surrounding the first semiconductor chip and the chip stack on the upper surface of the interposer substrate, manufacturing a stack package by forming a metal layer on an upper surface of the molding layer, an upper surface of the chip stack and an upper surface of the first semiconductor chip, and mounting the stack package on a package substrate, wherein the metal layer includes a shape memory alloy configured to reversibly change a shape thereof according to a temperature of the metal layer.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a plan view illustrating a semiconductor package according to embodiments of the inventive concept;

FIG. 2 is a cross-sectional view, illustrating a semiconductor package according to embodiments of the inventive concept, taken along line B-B′ of FIG. 1;

FIG. 3 is an enlarged diagram of part N of FIG. 2 illustrating a portion of a semiconductor package according to embodiments of the inventive concept;

FIGS. 4A and 4B are schematic diagrams illustrating a crystalline phase change of a first metal layer 710 according to a temperature change;

FIGS. 5 and 6 are cross-sectional views illustrating a semiconductor package according to embodiments of the inventive concept;

FIGS. 7 to 10 are cross-sectional views illustrating a method for manufacturing a semiconductor package according to embodiments of the inventive concept; and

FIG. 11 is a schematic diagram illustrating a role of a metal layer of a semiconductor package according to embodiments of the inventive concept.

### DETAILED DESCRIPTION

Hereinafter, a semiconductor package according to the inventive concept will be described with reference to the drawings, in which various embodiments are shown. The invention may, however, be embodied in many different forms and should not be construed as limited to the example embodiments set forth herein. It should also be emphasized that the disclosure provides details of alternative examples, but such listing of alternatives is not exhaustive. Furthermore, any consistency of detail between various examples should not be interpreted as requiring such detail. The language of the claims should be referenced in determining the requirements of the invention.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

As used herein, components described as being “electrically connected” are configured such that an electrical signal can be transferred from one component to the other (although such electrical signal may be attenuated in strength as it is transferred and may be selectively transferred). Moreover, components that are “directly electrically connected” form a common electrical node through electrical connections by one or more conductors, such as, for example, wires, pads, internal electrical lines, through vias, etc. As such, directly electrically connected components do not include components electrically connected through active elements, such as transistors or diodes.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first”) in a particular claim may be described elsewhere with a different ordinal number (e.g., “second”) in the specification or another claim.

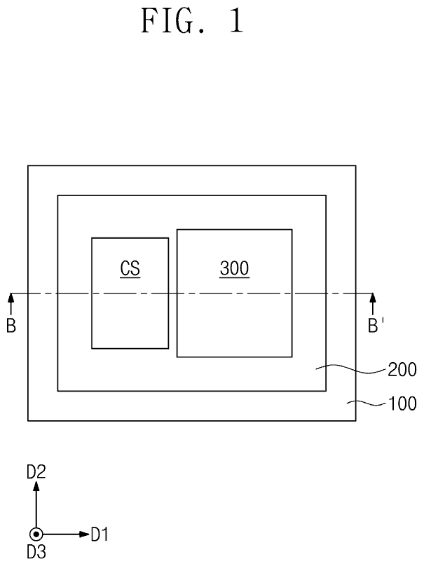

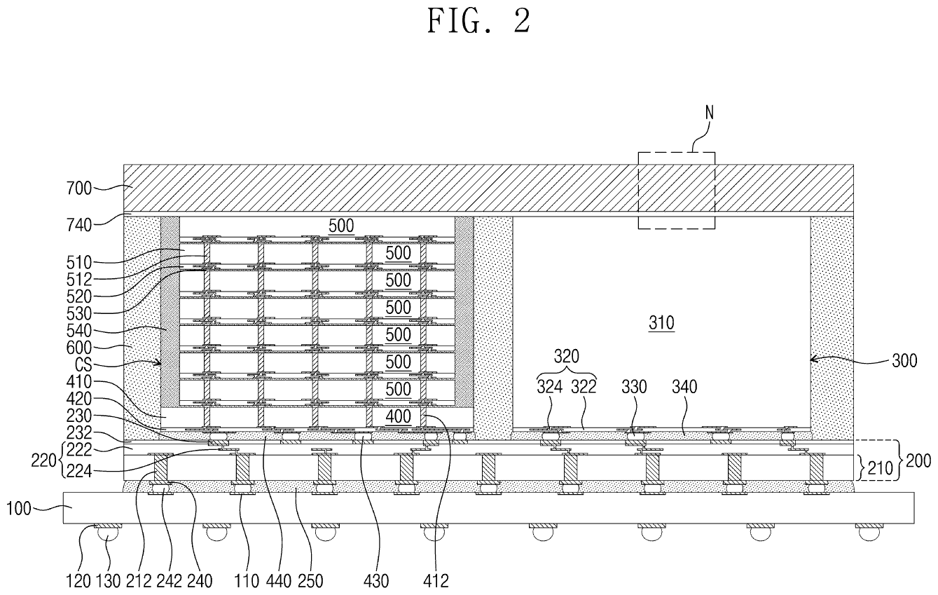

FIG. 1 is a plan view illustrating the semiconductor package according to embodiments of the inventive concept. FIG. 2 is a cross-sectional view, illustrating the semiconductor package according to embodiments of the inventive concept, taken along line B-B′ of FIG. 1. Referring to FIG. 1, the semiconductor package may include a package substrate 100, an interposer substrate 200, a chip stack CS and a first semiconductor chip 300. In the present specification, a first direction D1 may be a direction parallel to an upper surface of the package substrate 100. A second direction D2 may be a direction parallel to the upper surface of the package substrate 100 and perpendicular to the first direction D1. A third direction D3 may mean a direction perpendicular to the upper surface of the package substrate 100 and perpendicular to the second direction D2 and the first direction D1. The interposer substrate 200 may be provided on the package substrate 100. The first semiconductor chip 300 and the chip stack CS may be provided on the interposer substrate 200. The chip stack CS may be disposed spaced apart from the first semiconductor chip 300 on the interposer substrate 200 in the first direction D1.

It is illustrated in FIG. 1 that one first semiconductor chip 300 and one chip stack CS are provided on the interposer substrate 200, but the inventive concept is not limited thereto. The first semiconductor chip 300 and the chip stack CS may be provided in plurality. For example, there may be a plurality of first semiconductor chips 300 with each of the first semiconductor chip 300 may be spaced apart from each other on the interposer substrate 200 in the second direction D2. There may be a plurality of chip stacks CS with each chip stack CS provided spaced apart in the first direction D1 of a respective first semiconductor chip 300 and/or spaced apart in an opposite direction of the first direction D1. At least one of the chip stacks CS may be disposed in each of the first direction D1 he opposite direction of the first direction D1 relative to a respective first semiconductor chip 300. For example, the chip stacks CS may be disposed in at least two columns extending in the second direction D2. The two columns of the chip stacks CS may be spaced apart from each other in the first direction D1. The first semiconductor chips 300 may be provided as a single column between the two columns of the chip stacks CS. The first semiconductor chips 300 and the chip stacks CS may be disposed on an upper surface of the interposer substrate 200 like the above.

Alternatively, the first semiconductor chip 300 and a plurality of chip stacks CS may be provided. For example, the chip stacks CS may be disposed, on one side of the first semiconductor chip 300, spaced apart from each other in the second direction D2. The quantity and location of the first semiconductor chips 300 and the chip stacks CS may be changed as needed. Hereinafter, a description will be made with

reference to the embodiment of FIG. 1. Configurations of the package substrate 100, the interposer substrate 200, the first semiconductor chips 300 and the chip stacks CS will be described in more detail with reference to FIG. 2 below.

Referring to FIG. 2, the package substrate 100 may be a redistribution substrate. For example, although not shown, the package substrate 100 may include one substrate wiring layer, or at least two substrate wiring layers mutually stacked. In the present specification, the substrate wiring layer may be a wiring layer formed by patterning each of an insulating material layer and a conductive material layer. Each of the substrate wiring layers may include an insulating pattern and a conductive pattern in the insulating pattern. The conductive pattern of any one substrate wiring layer may be electrically connected to the conductive pattern of another adjacent substrate wiring layer.

The package substrate 100 may have an upper substrate pad 110. The upper substrate pad 110 may be an upper portion of the conductive pattern of a substrate wiring layer disposed on an uppermost end among the substrate wiring layers, or a separate pad electrically connected to the conductive pattern in the substrate wiring layer. The upper substrate pad 110 may be disposed on the upper surface of the package substrate 100. The upper substrate pad 110 may be coplanar with the upper surface of the package substrate 100 to be exposed onto the package substrate 100. However, the inventive concept is not limited thereto, and the upper substrate pad 110 may protrude from the upper surface of the package substrate 100. The upper substrate pad 110 may be provided in plurality.

It is described in FIG. 2 that the package substrate 100 is a redistribution substrate, but the inventive concept is not limited thereto. According to other embodiments, the package substrate 100 may be a printed circuit board (PCB). In this case, the package substrate 100 may have an internal wiring pattern provided in the package substrate 100. For example, the package substrate 100 may have a structure in which an insulating pattern and the internal wiring pattern are alternately stacked. In this case, the upper substrate pad 110 may be a separate pad electrically connected to the internal wiring pattern, or a portion of the internal wiring pattern protruding onto the upper surface of the package substrate 100. Hereinafter, description will be made referring to the embodiment of FIGS. 1 and 2.

A lower substrate pad 120 and a substrate connection terminal 130 may be provided on a lower surface of the package substrate 100. The lower substrate pad 120 may be a separate pad disposed on the lower surface of the package substrate 100 to be connected to the conductive pattern of the package substrate 100, or a portion of the conductive pattern exposed onto the lower surface of the package substrate 100. However, the inventive concept is not limited thereto, and the lower substrate pad 120 may protrude from the lower surface of the package substrate 100. The substrate connection terminal 130 may include a solder ball, a solder bump, or the like. The lower substrate pad 120 and the substrate connection terminal 130 may be provided in plurality.

The interposer substrate 200 may include a core layer 210 and an interposer wiring layer 220. The core layer 210 may include silicon (Si). The core layer 210 may include an interposer penetration via 212 penetrating an inside of the core layer 210. An upper surface of the interposer penetration via 212 may be exposed at an upper surface of the core layer 210. A lower surface of the interposer penetration via 212 may be exposed at a lower surface of the core layer 210. The interposer penetration via 212 may be provided in plurality.

The interposer wiring layer 220 may be provided on the upper surface of the core layer 210. The interposer wiring layer 220 may include an interposer insulating pattern 222 and an interposer wiring pattern 224 in the interposer insulating pattern 222. The upper surface of the exposed interposer penetration via 212 may be electrically connected to the interposer wiring pattern 224. A first substrate pad 230 may be provided on the upper surface of the interposer substrate 200. The first substrate pad 230 may be a portion of the interposer wiring pattern 224 exposed from the interposer insulating pattern 222 of the interposer wiring layer 220, or a separate pad disposed on the interposer wiring layer 220 to be connected to the interposer wiring pattern 224.

A substrate protection layer 232 covering the interposer substrate 200 may be provided on the upper surface of the interposer substrate 200. The substrate protection layer 232 may surround the first substrate pad 230, covering the upper surface of the interposer substrate 200. The first substrate pad 230 may be exposed at an upper surface of the substrate protection layer 232. The substrate protection layer 232 may include insulating polymer or photosensitive polymer. In some embodiments, the substrate protection layer 232 may not be provided.

A second substrate pad 240 and an interposer connection terminal 242 may be provided on a lower surface of the interposer substrate 200. The second substrate pad 240 may be electrically connected to the lower surface of the exposed interposer penetration via 212. The interposer connection terminal 242 may be disposed on a lower surface of the second substrate pad 240. The interposer connection terminal 242 may include a solder ball, a solder bump, or the like. The second substrate pad 240 and the interposer connection terminal 242 may be electrically connected to the first substrate pad 230 through the interposer penetration via 212. The first substrate pad 230 and the second substrate pad 240 may be electrically connected to each other by the interposer wiring pattern 224. The first substrate pad 230 and the second substrate pad 240 may include a conductive material such as metal. For example, the first substrate pad 230 and the second substrate pad 240 may include copper (Cu).

The interposer substrate 200 may be mounted on the package substrate 100 through the interposer connection terminal 242. One end of the interposer connection terminal 242 may be in contact with the second substrate pad 240. The other end of the interposer connection terminal 242 may be in contact with the upper substrate pad 110 of the package substrate 100. A first underfill layer 250 may be provided between the lower surface of the interposer substrate 200 and the upper surface of the package substrate 100. The first underfill layer 250 may fill a space between the package substrate 100 and the interposer substrate 200, and may surround the second substrate pad 240 and the interposer connection terminal 242. The first substrate pad 230, the second substrate pad 240, and the interposer connection terminal 242 may be provided in plurality. The interposer substrate 200 may redistribute electrical signals of the chip stack CS and the first semiconductor chip 300.

The first semiconductor chip 300 may be disposed on the upper surface of the interposer substrate 200. The first semiconductor chip 300 may be provided on the interposer substrate 200 in a face-down orientation. A lower surface of the first semiconductor chip 300 may be an active surface.

The first semiconductor chip 300 may include a first semiconductor substrate 310. The first semiconductor substrate 310 may include a semiconductor material. For example, the first semiconductor substrate 310 may include silicon (Si). An integrated device or integrated circuits may be formed on a lower surface of the first semiconductor substrate 310. The integrated device or integrated circuits may include a logic circuit. For example, the first semiconductor chip 300 may be a logic chip.

A first wiring layer 320 may be provided on the lower surface of the first semiconductor substrate 310. The first wiring layer 320 may have a first insulating pattern 322 and a first wiring pattern 324 provided in the first insulating pattern 322. The first insulating pattern 322 may cover the integrated device or integrated circuits on the lower surface of the first semiconductor substrate 310. The first wiring pattern 324 may be connected to an integrated device or integrated circuits formed on the first semiconductor substrate 310.

The first semiconductor chip 300 may be mounted on the interposer substrate 200. For example, the first semiconductor chip 300 may be electrically connected to the interposer substrate 200 through a first connection terminal 330. The first connection terminal 330 may be provided between the first substrate pad 230 and a first pad provided on the lower surface of the first semiconductor chip 300. In this case, the first pad may be a portion of the first wiring pattern 324 exposed in the first insulating pattern 322 of the first wiring layer 320, or a separate pad disposed on the first insulating pattern 322 of the first wiring layer 320 to be connected to the first wiring pattern 324. The first connection terminal 330 and the first pad may be provided in plurality.

A second underfill layer 340 may be provided between the upper surface of the interposer substrate 200 and the lower surface of the first semiconductor chip 300. The second underfill layer 340 may fill a space between the interposer substrate 200 and the first semiconductor chip 300, and may surround the first substrate pad 230, the first pad, and the first connection terminal 330.

The chip stack CS may be provided on the interposer substrate 200. The chip stack CS may be disposed horizontally spaced apart from the first semiconductor chip 300 on the interposer substrate 200. The chip stack CS may include a base chip 400, second semiconductor chips 500 stacked on the base chip 400 and a first molding layer 540 surrounding the second semiconductor chips 500. Hereinafter, a configuration of the chip stack CS will be described in detail.

The base chip 400 may include a base substrate 410. The base substrate 410 may be a semiconductor substrate. For example, the base substrate 410 may be a wafer-level semiconductor substrate made of a semiconductor material such as silicon (Si). A lower surface of the base chip 400 may be an active surface. For example, an integrated device or integrated circuits may be formed on a lower surface of the base substrate 410. For example, the integrated device or integrated circuits may include a memory circuit. The base chip 400 may be a memory chip such as a DRAM, an SRAM, an MRAM, or a flash memory. Alternatively, the integrated device or integrated circuits may include a logic circuit. In this case, the base chip 400 may be a logic chip.

The base chip 400 may include a base wiring layer 420 and a base penetration via 412. The base wiring layer 420 may be provided on the lower surface of the base substrate 410. The base wiring layer 420 may include the integrated device or integrated circuits. The base penetration via 412 may penetrate through the base chip 400 in a direction perpendicular to the upper surface of the interposer substrate 200 (e.g., a vertical direction). The base penetration via 412 and the base wiring layer 420 may be electrically connected to each other.

The base chip 400 may further include a protection layer and a second connection terminal 430. Although not shown, the protection layer may be disposed on the lower surface of the base chip 400 to cover the base wiring layer 420. The protection layer may include silicon oxide (SiO), or silicon nitride (SiN). The second connection terminal 430 may be provided on the lower surface of the base chip 400. The second connection terminal 430 may be electrically connected to the integrated device or integrated circuits of the base wiring layer 420. The second connection terminal 430 may be provided in plurality.

The second semiconductor chip 500 may be provided on the base chip 400. The second semiconductor chip 500 may have a smaller width than the base chip 400. The second semiconductor chip 500 and the base chip 400 of the chip stack CS may have smaller thicknesses than the first semiconductor chip 300. The second semiconductor chip 500 may include a second semiconductor substrate 510, a second wiring layer 520 and a second chip penetration via 512.

The second semiconductor substrate 510 may be a semiconductor substrate. For example, the second semiconductor substrate 510 may include silicon (Si). A lower surface of the second semiconductor chip 500 may be an active surface. For example, an integrated device or integrated circuits may be formed on a lower surface of the second semiconductor substrate 510. For example, the integrated device or integrated circuits may include a memory circuit. The second semiconductor chip 500 may be a memory chip such as a DRAM, an SRAM, an MRAM or a flash memory.

The second semiconductor chip 500 may include a second wiring layer 520 and a second chip penetration via 512. The second wiring layer 520 may be provided on the lower surface of the second semiconductor substrate 510. The second wiring layer 520 may include an integrated device or integrated circuits. The second chip penetration via 512 may penetrate through the second semiconductor chip 500 in a direction perpendicular to the upper surface of the interposer substrate 200. The second chip penetration via 512 and the second wiring layer 520 may be electrically connected to each other. Connection bumps 530 may be provided on the lower surface of the second semiconductor chip 500. The connection bumps 530 may electrically connect the base chip 400 and the second semiconductor chip 500 between the base chip 400 and the second semiconductor chip 500. The connection bumps 530 may be electrically connected to the integrated device or integrated circuits of the second wiring layer 520.

The second semiconductor chip 500 may be provided in plurality. A plurality of second semiconductor chips 500 may be stacked on the base chip 400. For example, 4 to 32 of the second semiconductor chips 500 may be stacked on the base chip 400. The connection bumps 530 may be respectively provided between the second semiconductor chips 500. In this case, an uppermost second semiconductor chip 500 may not include the second chip penetration via 512. In addition, the uppermost second semiconductor chip 500 may have a greater thickness than other second semiconductor chips 500 disposed thereunder.

Although not shown, first adhesive layers may be provided between the second semiconductor chips 500. The first adhesive layers may include a non-conductive film (NCF). The first adhesive layers may surround the connection bumps 530 between the second semiconductor chips 500, and may prevent an electrical short circuit between the connection bumps 530 from occurring.

The first molding layer 540 may be disposed on an upper surface of the base chip 400. The first molding layer 540 may cover the upper surface of the base chip 400. The first molding layer 540 may surround the second semiconductor chips 500. An upper surface of the first molding layer 540 may be coplanar with an upper surface of the uppermost second semiconductor chip 500. The uppermost second semiconductor chip 500 may be exposed onto the upper surface of the first molding layer 540. The first molding layer 540 may include an insulating polymer material. For example, the first molding layer 540 may include an epoxy molding compound (EMC).

The chip stack CS may be mounted on the interposer substrate 200. For example, the chip stack CS may be connected to the first substrate pad 230 disposed on the upper surface of the interposer substrate 200 through the second connection terminal 430 of the base chip 400. The second connection terminal 430 may be in contact with the upper surface of the first substrate pad 230 and a lower surface of the base wiring layer 420 to electrically connect the chip stack CS and the interposer substrate 200.

A third underfill layer 440 may be provided between the interposer substrate 200 and the chip stack CS. The third underfill layer 440 may fill a space between the interposer substrate 200 and the base chip 400, and may surround the first substrate pad 230 and the second connection terminal 430.

A second molding layer 600 may be disposed on the upper surface of the interposer substrate 200. The second molding layer 600 may surround the first semiconductor chip 300, the second underfill layer 340, the chip stack CS and the third underfill layer 440. An upper surface of the second molding layer 600 may be coplanar with the upper surface of the uppermost second semiconductor chip 500 of the chip stack CS and an upper surface of the first semiconductor chip 300. The first semiconductor chip 300 and the uppermost second semiconductor chip 500 may be exposed at the upper surface of the second molding layer 600. The second molding layer 600 may include an insulating polymer material. For example, the second molding layer 600 may include an epoxy molding compound (EMC).

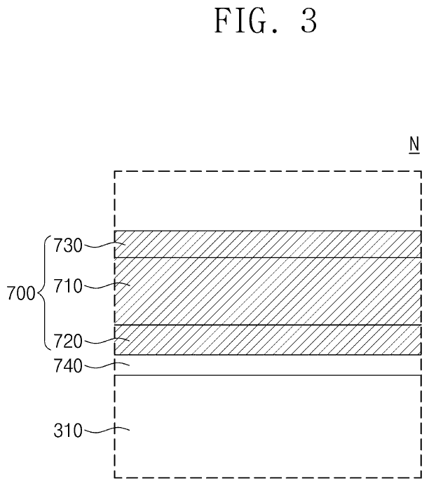

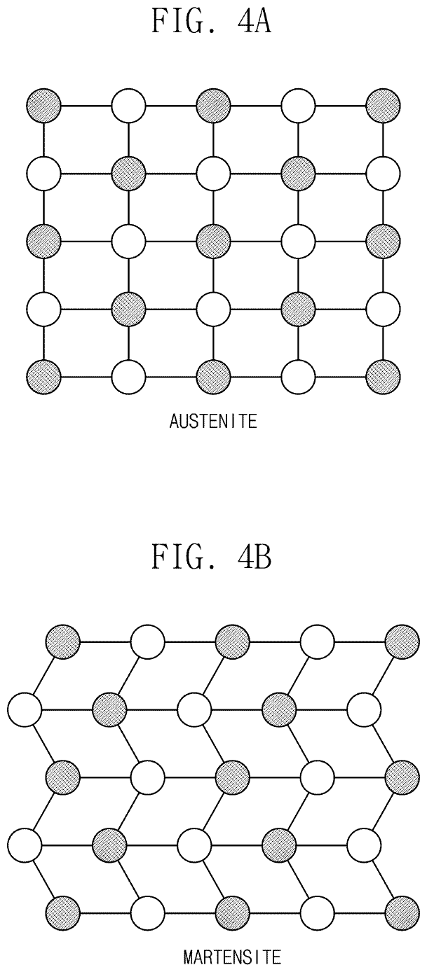

A metal layer 700 may be provided on the upper surface of the second molding layer 600, an upper surface of the chip stack CS, and the upper surface of the first semiconductor chip 300. The metal layer 700 may cover the upper surface of the second molding layer 600, the upper surface of the chip stack CS and the upper surface of the first semiconductor chip 300. Hereinafter, a configuration and a shape of the metal layer 700 will be described in more detail with reference to FIGS. 3 and 4.

FIG. 3 is an enlarged diagram, of area N of FIG. 2, illustrating a portion of the semiconductor package according to embodiments of the inventive concept. FIGS. 4A and 4B are schematic diagrams illustrating a crystalline phase change of the first metal layer 710 according to a temperature change. Referring to FIG. 3, the metal layer 700 may include a first metal layer 710, a second metal layer 720, and a third metal layer 730.

The first metal layer 710 may include a shape memory alloy. The shape memory alloy may be an alloy having a property of returning to an original shape (e.g., a shape before being deformed) by heating, even when the original shape has been deformed into a different shape. The first metal layer 710 may include an alloy composed of at least two metals of nickel, titanium, copper, zinc, aluminum, or silver. The first metal layer 710 may have a thickness in the third direction D3 between 1 μm and 300 μm.

The first metal layer 710 may reversibly change a shape thereof according to temperature. The first metal layer 710 may reversibly change a crystalline phase according to temperature. Referring to FIG. 4A, the first metal layer 710 may have an austenite phase at a temperature higher than a crystalline phase change temperature of the first metal layer 710. Referring to FIG. 4B, the first metal layer 710 may have a martensite phase at a temperature lower than the crystalline phase change temperature of the first metal layer 710. For example, when the first metal layer 710 is cooled to a temperature equal to or lower than the crystalline phase change temperature, the first metal layer 710 may change from the austenite phase to the martensite phase. When the first metal layer 710 is heated to a temperature equal to or higher than the crystalline phase change temperature, the first metal layer 710 may recover from the martensite phase to the austenite phase. In the present description, the crystalline phase change temperature may mean a temperature range rather than a single temperature. The crystalline phase change temperature of the first metal layer 710 may be about 70° C. to about 110° C., but the inventive concept is not limited thereto.

The first metal layer 710 may have a material property that changes according to a crystalline phase thereof. For example, the first metal layer 710 may have a greater mechanical strength in the austenite phase than in the martensite phase. Accordingly, a shape of the first metal layer 710 may be deformed into a different shape by an external stress at a temperature lower than the crystalline phase change temperature (e.g., when in the martensite phase). The first metal layer 710 may maintain the original shape thereof at a temperature higher than the crystalline phase change temperature. In this case, the original state of the first metal layer 710 may have a shape in which each of an upper surface and a lower surface of the first metal layer 710 is flat.

Although the first metal layer 710 may be deformed at the temperature equal to or lower than the crystalline phase change temperature, when the first metal layer 710 is heated to the temperature equal to or higher than the crystalline phase change temperature, the first metal layer 710 may return to the original state having the shape before being deformed (e.g., the original shape). For example, the first metal layer 710 may have a first shape at a first temperature. The first temperature may mean an arbitrary temperature lower than the crystalline phase change temperature. The first metal layer 710 may have a second shape different from the first shape at a second temperature higher than the crystalline phase change temperature. When the first metal layer 710 is heated from the first temperature to the second temperature, the first metal layer 710 may recover the second shape. The second shape may be a shape of the original state of the first metal layer 710. A difference between a level of a central portion of the first metal layer 710 and a level of an outer portion of the first metal layer 710 may be greater in the first shape than in the second shape (e.g., the first shape may have a bowed or convex upper surface).

The second metal layer 720 may be interposed between the first semiconductor chip 300 and the first metal layer 710. The second metal layer 720 may be provided so as to improve an adhesive force between the first semiconductor chip 300 and the first metal layer 710. The second metal layer 720 may include a conductive material such as metal. For example, the second metal layer 720 may include aluminum (Al), but the inventive concept is not limited thereto.

The third metal layer 730 may be provided on an upper surface of the first metal layer 710. The third metal layer 730 may cover the upper surface of the first metal layer 710. The third metal layer 730 may include a conductive material such as metal. For example, the third metal layer 730 may include gold (Au). In some embodiments, the second metal layer 720 and the third metal layer 730 may not be present. For example, the metal layer 700 may have a single layer composed of the first metal layer 710.

A second adhesive layer 740 may be provided on a lower surface of the metal layer 700. The second adhesive layer 740 may be interposed between the upper surface of the second molding layer 600 and the lower surface of the metal layer 700, between the upper surface of the first semiconductor chip 300 and the lower surface of the metal layer 700, and between the upper surface of the chip stack CS and the lower surface of the metal layer 700. The metal layer 700 may be attached to the upper surfaces of the second molding layer 600, the first semiconductor chip 300 and the chip stack CS by the second adhesive layer 740. The second adhesive layer 740 may include thermosetting polymer. In some embodiments, the second adhesive layer 740 may not be present.

Since the metal layer 700 is provided on the upper surfaces of the first semiconductor chip 300 and the chip stack CS, heat generated by the chip stack CS and the first semiconductor chip 300 may be transferred through the metal layer 700 to the outsides thereof. For example, the semiconductor package may have improved heat dissipation characteristics as a result.

In embodiments below, components that may be the same or substantially the as the components described in relations to the embodiments of FIGS. 1 to 4 may use the same reference numerals and symbols, and a description thereof may be omitted or briefly made for convenience of description. For example, in the follow description, a difference between the embodiments in FIGS. 1 to 4 and the embodiments below will be mainly described.

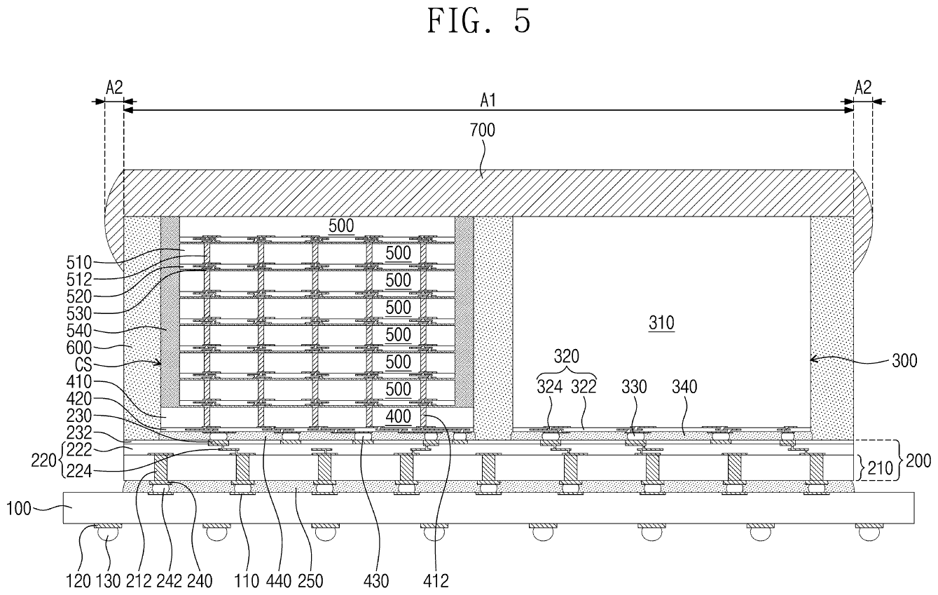

It is illustrated in FIG. 2 that a side surface of the metal layer 700 is aligned with a side surface of the second molding layer 600, but the inventive concept is not limited thereto. FIG. 5 is a cross-sectional view illustrating the semiconductor package according to embodiments of the inventive concept. Referring to FIG. 5, the metal layer 700 may be provided on the upper surface of the second molding layer 600, the upper surface of the chip stack CS and the upper surface of the first semiconductor chip 300. In this case, the second molding layer 600, the chip stack CS, the first semiconductor chip 300 and the metal layer 700 may be the same, substantially the same, or similar to what is described with reference to FIGS. 1 to 4. For example, the first metal layer 710 of the metal layer 700 may include the shape memory alloy, and may have crystalline phases different according to temperature.

However, unlike FIGS. 1 to 3, the metal layer 700 may protrude onto the side surface of the second molding layer 600. The metal layer 700 may include a first region A1 covering the upper surfaces of the second molding layer 600, the chip stack CS, and the first semiconductor chip 300, and a second region A2 protruding in an outer direction of the side surface of the second molding layer 600. For example, the first region A1 of the metal layer 700 may be a region vertically overlapping the upper surfaces of the second molding layer 600, the chip stack CS, and the first semiconductor chip 300. The second region A2 of the metal layer 700 may be a remaining region of the metal layer 700 excluding the first region A1. In the second region A2, the metal layer 700 may extend from the upper surface of the second molding layer 600 to the side surface of the second molding layer 600 to at least partially cover the side surface of the second molding layer 600.

In this case, the second adhesive layer 740 may not be provided on the lower surface of the metal layer 700. The lower surface of the metal layer 700 may be in contact with the upper surfaces of the second molding layer 600, the chip stack CS and the first semiconductor chip 300. In addition, as described with reference to FIG. 2, the metal layer 700 may be composed of a single layer of the first metal layer 710 as needed. For example, the first metal layer 710 and the third metal layer 730 may not be provided.

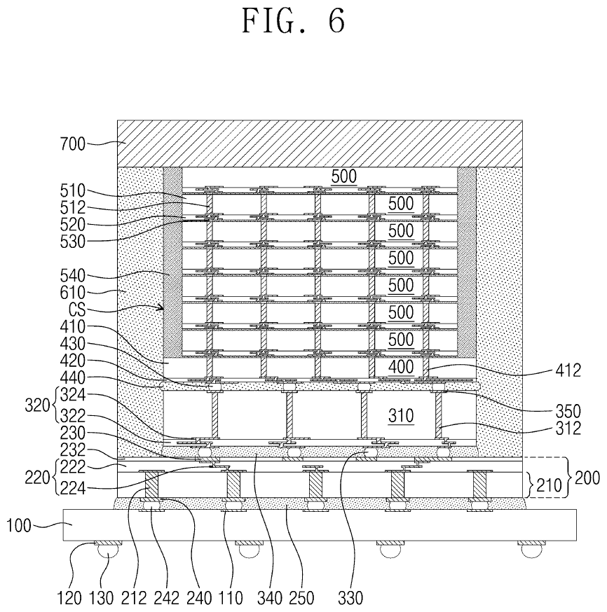

It is illustrated in FIGS. 1 and 2 that the first semiconductor chip 300 and the chip stack CS are horizontally spaced apart from each other on the interposer substrate 200, but the inventive concept is not limited thereto. FIG. 6 is a cross-sectional view for describing the semiconductor package according to embodiments of the inventive concept. Referring to FIG. 6, at least one chip stack CS may be provided on the first semiconductor chip 300. Hereinafter, for convenience of description, it is described assuming that one chip stack CS is stacked on the first semiconductor chip 300. The first semiconductor chip 300 may be provided on the interposer substrate 200. The chip stack CS may be provided on the upper surface of the first semiconductor chip 300. In this case, a configuration of each of the interposer substrate 200, the first semiconductor chip 300, and the chip stack CS may be the same, substantially the same, or similar to what is described with reference to FIGS. 1 and 2. For example, the chip stack CS may include the base chip 400 and the second semiconductor chips 500 stacked on the base chip 400.

However, unlike the embodiment shown in FIG. 2, the first semiconductor chip 300 may further include a second pad 350 and a first chip penetration via 312 penetrating through an inside thereof. The first chip penetration via 312 may penetrate through the first semiconductor substrate 310. A portion of the lower surface of the first chip penetration via 312 may be in contact with the first wiring pattern 324. The first chip penetration via 312 may be electrically connected to the integrated device and the integrated circuits of the first semiconductor chip 300 through the first wiring pattern 324. An upper surface of the first chip penetration via 312 may be in contact with a lower surface of the second pad 350. The second pad 350 may be provided on an upper surface of the first semiconductor substrate 310. The second pad 350 may be exposed or protrude onto the upper surface of the first semiconductor substrate 310. The first chip penetration via 312 and the second pad 350 may include a conductive material such as metal. For example, the first chip penetration via 312 and the second pad 350 may include copper (Cu). The first chip penetration via 312 and the second pad 350 may be provided in plurality. For example, each of the first chip penetration vias 312 may be provided on the lower surface of each of the second pads 350 corresponding thereto.

The first semiconductor chip 300 may be mounted on the interposer substrate 200. For example, the first semiconductor chip 300 may be electrically connected to the interposer substrate 200 through the first connection terminal 330. The second underfill layer 340 may be provided between the upper surface of the interposer substrate 200 and the lower surface of the first semiconductor chip 300. The second underfill layer 340 may fill a space between the interposer substrate 200 and the first semiconductor chip 300, and may surround the first substrate pad 230, the first pad and the first connection terminal 330.

The chip stack CS may be mounted on the first semiconductor chip 300. For example, the chip stack CS may be electrically connected to the first semiconductor chip 300 through the second connection terminal 430. The second connection terminal 430 of the base chip 400 may be electrically connected to the second pad 350. The chip stack CS may be electrically connected to the first semiconductor chip 300 through the second connection terminal 430, the second pad 350, and the first chip penetration via 312. The third underfill layer 440 may fill a space between the first semiconductor chip 300 and the base chip 400, and may surround the second connection terminal 430.

A third molding layer 610 surrounding the first semiconductor chip 300 and the chip stack CS may be provided on the interposer substrate 200. The third molding layer 610 may surround sides of the chip stack CS and the first semiconductor chip 300. The upper surface of the chip stack CS may be exposed onto the third molding layer 610. An upper surface of the third molding layer 610 and the upper surface of the chip stack CS may be coplanar with each other. The metal layer 700 may be provided on the upper surface of the chip stack CS. A configuration of the metal layer 700 may be substantially the same as what is described with reference to FIGS. 1 to 4. The metal layer 700 may cover the upper surface of the chip stack CS and the upper surface of the third molding layer 610. Although not shown, a third adhesive layer may be provided on the lower surface of the metal layer 700 as needed. The third adhesive layer may be interposed between the upper surface of the chip stack CS and the lower surface of the metal layer 700, and between the upper surface of the third molding layer 610 and the lower surface of the metal layer 700. The metal layer 700 may be attached onto the chip stack CS and the third molding layer 610 through the third adhesive layer. The third adhesive layer may include thermosetting polymer.

It is illustrated in FIG. 6 that the first semiconductor chip 300 has the same width as the chip stack CS, but the inventive concept is not limited thereto. The first semiconductor chip 300 may have a greater width than the chip stack CS. In addition, it is illustrated in FIG. 6 that the side surface of the metal layer 700 is aligned with a side surface of the third molding layer 610, but the inventive concept is not limited thereto. The metal layer 700 may extend from the upper surface of the third molding layer 610 to the side surface of the third molding layer 610 to at least partially cover the side surface of the third molding layer 610.

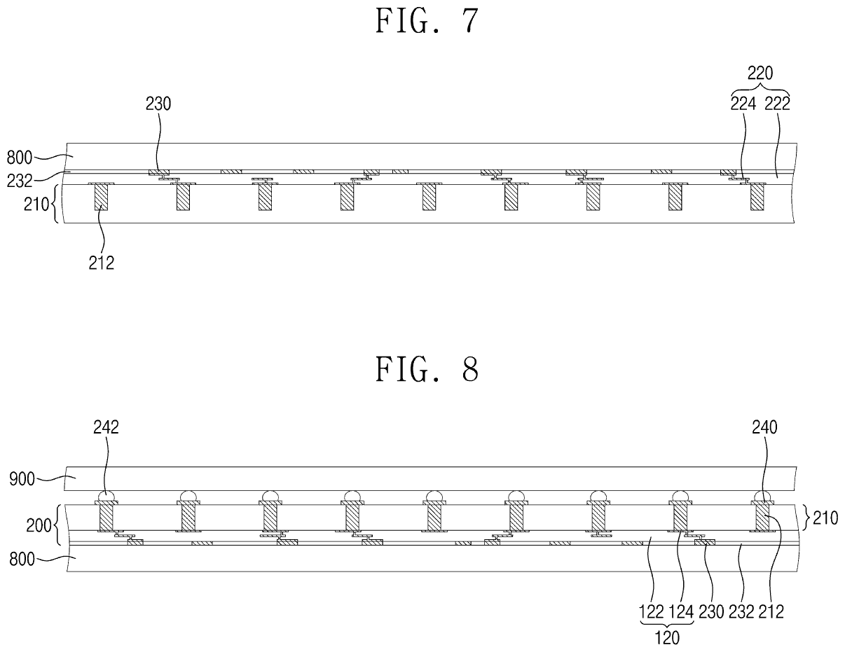

FIGS. 7 to 10 are cross-sectional views illustrating a method for manufacturing the semiconductor package according to embodiments of the inventive concept. Referring to FIG. 7, the core layer 210 may be formed. The core layer 210 may include the interposer penetration via 212 at least partially penetrating the inside of the core layer 210. The upper surface of the interposer penetration via 212 may be exposed onto the upper surface of the core layer 210. The lower surface of the interposer penetration via 212 may not be exposed onto the lower surface of the core layer 210.

The interposer wiring layer 220 may be formed on the core layer 210. For example, the interposer insulating pattern 222 may be formed by applying an insulating material on the core layer 210. The interposer wiring pattern 224 may be formed by forming a conductive layer on the interposer insulating pattern 222, and then patterning the conductive layer. The interposer wiring pattern 224 may be electrically connected to an upper surface of the exposed interposer penetration via 212. The interposer wiring pattern 224 may be partially exposed onto an upper surface of the interposer insulating pattern 222.

The substrate protection layer 232 and the first substrate pad 230 may be formed on the interposer wiring layer 220. The substrate protection layer 232 may be formed by applying an insulating material on the interposer wiring layer 220. Penetration holes may be formed by performing an exposure process and a develop process on the substrate protection layer 232. The first substrate pad 230 may be formed by filling the penetration holes of the substrate protection layer 232 with a conductive material. The first substrate pad 230 may be partially electrically connected to the exposed interposer wiring pattern 224. An upper surface of the first substrate pad 230 may be exposed onto the substrate protection layer 232. A first carrier substrate 800 may be provided on the substrate protection layer 232.

Referring to FIG. 8, a result of FIG. 7 may be turned upside down (e.g., inverted). The first carrier substrate 800 may be disposed on a lower surface of the substrate protection layer 232. A grinding process may be performed on the upper surface of the core layer 210. The interposer penetration via 212 may be exposed onto the upper surface of the ground core layer 210. The second substrate pad 240 and the interposer connection terminal 242 may be formed on the upper surface of the ground core layer 210. The second substrate pad 240 may be electrically connected to the exposed interposer penetration via 212. The interposer substrate 200 may be formed like the above. A second carrier substrate 900 may be provided on the interposer connection terminal 242.

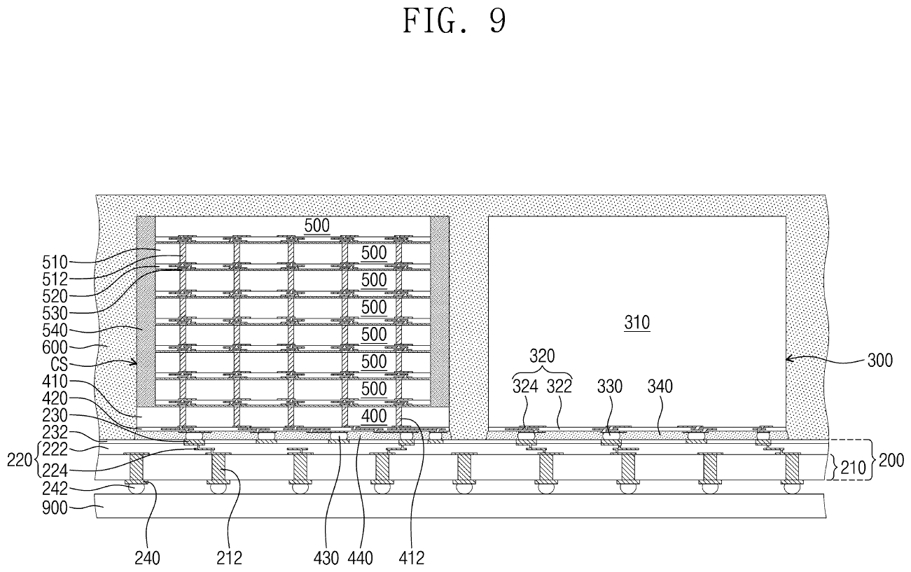

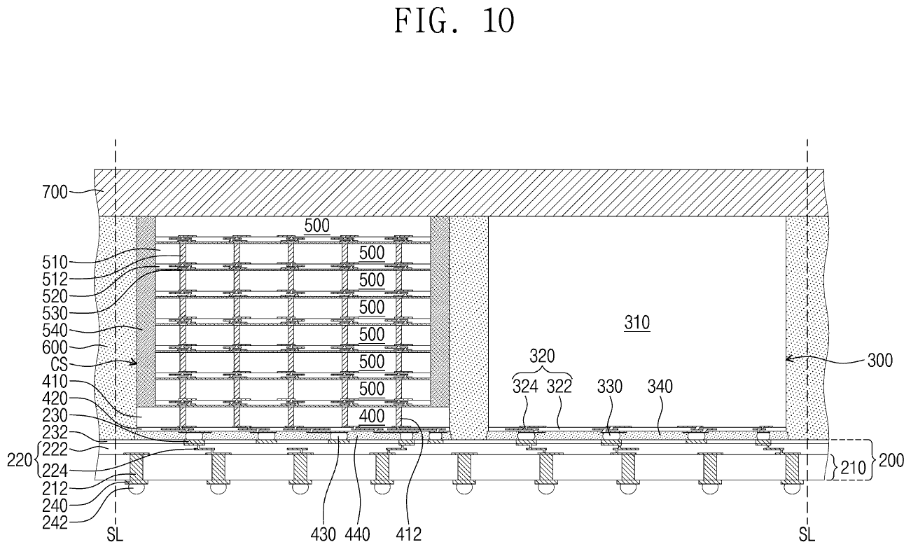

Referring to FIG. 9, a result of FIG. 8 may be turned upside down (e.g., inverted again to return to the original orientation). The interposer substrate 200 may be provided on an upper surface of the second carrier substrate 900. Thereafter, the first carrier substrate 800 may be removed. The first semiconductor chip 300 and the chip stack CS may be provided on the upper surface of the interposer substrate 200. In this case, the first semiconductor chip 300 and the chip stack CS may be substantially the same as what is described with reference to FIGS. 1 and 2.

The first semiconductor chip 300 may be mounted on the interposer substrate 200 through the first connection terminal 330. The first semiconductor chip 300 may be aligned with the interposer substrate 200 such that the first connection terminal 330 is disposed on the first substrate pad 230. The first connection terminal 330 may be in contact with the first substrate pad 230 by positioning the first semiconductor chip 300 close to the interposer substrate 200. The chip stack CS may be disposed horizontally spaced apart from the first semiconductor chip 300 on the interposer substrate 200. The second connection terminal 430 may be in contact with the first substrate pad 230 by positioning the chip stack CS close to the interposer substrate 200. Thereafter, a reflow process may be performed on the first connection terminal 330 and the second connection terminal 430. The first connection terminal 330 may connect the first wiring layer 320 and the first substrate pad 230. The second connection terminal 430 may connect the base wiring layer 420 and the first substrate pad 230.

The second underfill layer 340 surrounding the first connection terminal 330 may be provided on the lower surface of the first semiconductor chip 300. For example, the second underfill layer 340 may be a non-conductive adhesive or non-conductive film. When the second underfill layer 340 is the non-conductive adhesive, the second underfill layer 340 may be formed in a manner in which a liquid non-conductive adhesive is applied on the first semiconductor chip 300 through dispensing. When the second underfill layer 340 is the non-conductive film, the second underfill layer 340 may be formed in a manner in which the non-conductive film is attached on the first semiconductor chip 300.

The third underfill layer 440 surrounding the second connection terminal 430 may be provided on a lower surface of the chip stack CS. For example, the third underfill layer 440 may be a non-conductive adhesive or non-conductive film. When the third underfill layer 440 is the non-conductive adhesive, the third underfill layer 440 may be formed in a manner in which a liquid non-conductive adhesive is applied on the chip stack CS through dispensing. When the third underfill layer 440 is the non-conductive film, the third underfill layer 440 may be formed in a manner in which the non-conductive film is attached on the chip stack CS. The chip stack CS and the first semiconductor chip 300 may be mounted on the interposer substrate 200 like the above. The second molding layer 600 surrounding the chip stack CS and the first semiconductor chip 300 may be formed on the interposer substrate 200.

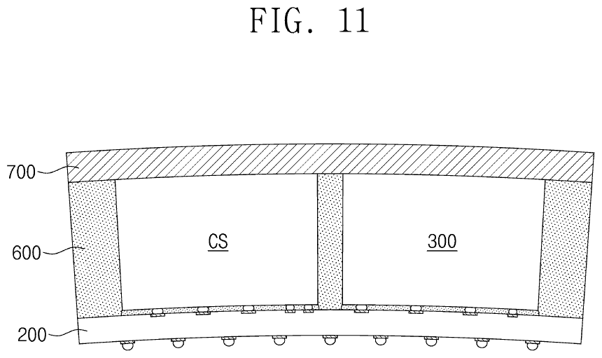

Referring to FIG. 10, a grinding process may be performed on the second molding layer 600. The upper surface of the chip stack CS and the upper surface of the first semiconductor chip 300 may be exposed onto the upper surface of the second molding layer 600 in the grinding process. An upper surface of the ground second molding layer 600, the upper surface of the chip stack CS, and the upper surface of the first semiconductor chip 300 may be coplanar with each other. The metal layer 700 may be provided on the upper surfaces of the chip stack CS and the first semiconductor chip 300. The metal layer 700 may be formed through physical vapor deposition (PVD).

However, the inventive concept is not limited thereto, and the metal layer 700 may be formed through chemical vapor deposition (CVD) or electroplating. When the metal layer 700 is formed through the chemical vapor deposition (CVD), an additional reaction material layer may be provided on the lower surface of the metal layer 700 as needed. The reaction material layer may be interposed between the upper surfaces of the second molding layer 600, the chip stack CS, and the first semiconductor chip 300 and the lower surface of the metal layer 700. The reaction material layer may include a conductive material such as metal. Alternatively, although not shown, the metal layer 700 may be attached through the second adhesive layer 740 (see FIG. 2) provided on the lower surface of the metal layer 700. The second adhesive layer 740 may be interposed between the upper surfaces of the second molding layer 600, the chip stack CS and the first semiconductor chip 300 and the lower surface of the metal layer 700. Thereafter, a sawing process may be performed along a sawing line SL to form first stack packages.

A process of forming the metal layer 700 may be performed at a temperature lower than the crystalline phase change temperature of the first metal layer 710. The first metal layer 710 may have a martensite phase in the process of forming the metal layer 700. Although not shown, in manufacturing processes of FIGS. 7 to 10, components of the semiconductor package may be warped. For example, a smile warpage (e.g., edges curve upward) or cry warpage (e.g., edges curved downward) may occur in the components of the semiconductor package in the manufacturing process of FIGS. 7 to 10. The components of the semiconductor package may be in different warpage states. Hereinafter, for convenience of description, it is described assuming that the cry warpage occurs in each of the components of the semiconductor package of FIG. 10.

FIG. 11 is a schematic diagram illustrating a role of the metal layer 700 of the semiconductor package according to embodiments of the inventive concept, and illustrates that the cry warpage occurs in the components of the first stack structure of FIG. 10. FIG. 11 briefly illustrates only some of the components for convenience of description. Referring to FIG. 11, the upper surface of the interposer substrate 200 may not be flat. An outer portion of the interposer substrate 200 may be warped toward an opposite direction of the third direction D3. A central portion of the upper surface of the interposer substrate 200 may have a higher level than the outer portion of the upper surface of the interposer substrate 200. The cry warpage may also occur in the chip stack CS and the first semiconductor chip 300. The upper surface of the chip stack CS and the upper surface of the first semiconductor chip 300 may not be flat. An outer portion of each of the chip stack CS and the first semiconductor chip 300 may be warped toward the opposite direction of the third direction D3. A central portion of the upper surface of the chip stack CS may have a higher level than an outer portion of the upper surface of the chip stack CS. The central portion of the upper surface of the first semiconductor chip 300 may have a higher level than the outer portion of the upper surface of the first semiconductor chip 300.

As described with reference to FIG. 10, the metal layer 700 may be formed on the chip stack CS and the first semiconductor chip 300. In this case, the chip stack CS and the first semiconductor chip 300 may be in a warped state. Since the process of forming the metal layer 700 is performed at a temperature lower than the crystalline phase change temperature of the first metal layer 710, the first metal layer 710 may have, in a manufacturing process of FIG. 10, a martensite phase having a low mechanical strength. A shape of the first metal layer 710 may be deformed by an external stress in the manufacturing process of FIG. 10. The deformed shape of the first metal layer 710 may be different from a shape of an original phase of the first metal layer 710. The shape of the original phase of the first metal layer 710 may mean a shape in which the upper surface and the lower surface of the first metal layer 710 are flat as described with reference to FIGS. 3 and 4. In the manufacturing process of FIG. 10, the metal layer 700 may be also warped like the other components of the first stack package. For example, the central portion of the upper surface of the metal layer 700 may have a higher level than the outer portion of the upper surface of the metal layer 700, like the interposer substrate 200, the chip stack CS and the first semiconductor chip 300.

Referring back to FIG. 2, the first stack package may be mounted on the package substrate 100. In this case, the package substrate 100 may be substantially the same as what is described with reference to FIG. 2. The first stack package may be aligned with the package substrate 100 such that the interposer connection terminal 242 is disposed on the upper substrate pad 110. The interposer connection terminal 242 may be in contact with the upper substrate pad 110 by positioning the first stack package close to the package substrate 100. Thereafter, the reflow process may be performed on the interposer connection terminal 242. The interposer connection terminal 242 may connect the interposer wiring layer 220 and the upper substrate pad 110. The semiconductor package of FIG. 2 may be manufactured like the above.

A temperature at which the reflow process is performed may be higher than the crystalline phase change temperature of the first metal layer 710. For example, the first metal layer 710 may change from the martensite phase to the austenite phase in a process of mounting the semiconductor package on the package substrate 100. The first metal layer 710 having the austenite phase may have a greater mechanical strength than the first metal layer 710 having the martensite phase. The first metal layer 710 may maintain the original phase thereof in the reflow process. For example, when the temperature increases in the reflow process, the first metal layer 710 may return from a phase having a deformed shape to the original phase thereof. In this case, warpage of the metal layer 700 may be alleviated. For example, the upper surface and the lower surface of the metal layer 700 may become flat. Since the first metal layer 710 recovers the original phase, the warpage of the other components (for example, the chip stack CS, the first semiconductor chip 300 and the interposer substrate 200) of the semiconductor package physically connected to the first metal layer 710 may be alleviated. For example, the upper surface and the lower surface of each of the chip stack CS, the first semiconductor chip 300 and the interposer substrate 200 may become flat.

The first metal layer 710 may compensate the warpage of the semiconductor package like the above. The first metal layer 710 of the metal layer 700 may serve to control the warpage of the semiconductor package. Accordingly, the semiconductor package with improved mechanical characteristics may be provided.

In addition, it is described in FIG. 10 that the metal layer 700 is formed and then the sawing process is performed along the sawing line SL, but the inventive concept is not limited thereto. A second stack package may be formed by performing the sawing process, and then forming the metal layer 700. For example, the metal layer 700 may be formed through the physical vapor deposition (PVD). The metal layer 700 may protrude onto the side surface of second molding layer 600 in a process of depositing the metal layer 700 on the second molding layer 600, the chip stack CS and the first semiconductor chip 300. The metal layer 700 may partially cover the side surface of the second molding layer 600. Thereafter, the semiconductor package of FIG. 6 may be manufactured by mounting the second stack package on the package substrate 100.

A process of mounting the second stack package on the package substrate 100 may be performed at a temperature higher than the crystalline phase change temperature of the first metal layer 710. The first metal layer 710 may recover the original phase of the first metal layer 710 by increasing the temperature. The first metal layer 710 may transfer a force that alleviates the warpage to the components of the second package in a process of recovering the original phase. Since the first metal layer 710 partially covers the side surface of the second molding layer 600, the force that alleviates the warpage may be transferred onto the second molding layer 600. Accordingly, the warpage of the other components (for example, the chip stack CS, the first semiconductor chip 300 and the interposer substrate 200) of the semiconductor package physically connected to the first metal layer 710 may be alleviated.

In a semiconductor package according to embodiments of the inventive concept, a metal layer composed of a shape memory alloy is formed on upper surfaces of semiconductor chips and a molding layer. Warpage of the semiconductor package may be controlled by using a mechanical property of the shape memory alloy. Accordingly, the semiconductor package with improved mechanical characteristics may be provided.

In addition, in the semiconductor package according to embodiments of the inventive concept, the metal layer may be formed on the upper surfaces of the semiconductor chips and the molding layer to effectively dissipate heat generated by the semiconductor chips. Accordingly, the semiconductor package with improved stability may be provided.

Although the embodiments of the present invention have been described, it is understood that the present invention should not be limited to these embodiments but various changes and modifications can be made by one ordinary skilled in the art within the spirit and scope of the present invention as hereinafter claimed. Therefore, it should be understood that the embodiments described above are exemplary in all respects and are not intended to be limiting.

What is claimed is:

1. A semiconductor package comprising:
a substrate;
a first semiconductor chip mounted on the substrate;
a chip stack disposed on the substrate spaced apart from the first semiconductor chip in a horizontal direction;
a molding layer on the substrate, the molding layer surrounding sides of the chip stack and sides of the first semiconductor chip; and
a first metal layer disposed on an upper surface of the molding layer, an upper surface of the first semiconductor chip, and an upper surface of the chip stack,
wherein the first metal layer includes a shape memory alloy that is configured to reversibly change a shape thereof according to a temperature of the first metal layer.

2. The semiconductor package of claim 1, wherein:
the first metal layer has a first shape at a first temperature lower than a crystalline phase change temperature of the shape memory alloy;
the first metal layer has a second shape different than the first shape at a second temperature higher than the crystalline phase change temperature of the shape memory alloy; and
when the first metal layer is configured such that when the first metal layer is heated from the first temperature to the second temperature, the first metal layer recovers the second shape.

3. The semiconductor package of claim 2, wherein the second shape has an upper surface that is flat.

4. The semiconductor package of claim 2, wherein a difference between a vertical level of a central portion of the first metal layer and a vertical level of an outer portion of the first metal layer is greater in the first shape of the first metal layer than in the second shape of the first metal layer.

5. The semiconductor package of claim 2, wherein the crystalline phase change temperature is between 70° C. and 110° C.

6. The semiconductor package of claim 1, further comprising a second metal layer on a lower surface of the first metal layer,
wherein the second metal layer includes aluminum.

7. The semiconductor package of claim 1, wherein the first metal layer has a thickness between 1 μm and 300 μm.

8. The semiconductor package of claim 1, wherein:
the chip stack comprises second semiconductor chips that are vertically stacked on one another;
each of the second semiconductor chips comprises a penetration via penetrating through an inside of a respective second semiconductor chip; and
the second semiconductor chips are electrically connected to each other through the penetration vias.

9. The semiconductor package of claim 1, further comprising an adhesive layer interposed between the first semiconductor chip and the first metal layer, and between the chip stack and the first metal layer.

10. The semiconductor package of claim 1, wherein the first metal layer extends from the upper surface of the molding layer to at least partially surround sides of the molding layer.

11. The semiconductor package of claim 1, wherein the first metal layer comprises an alloy comprising at least two metals of a group consisting of nickel, titanium, copper, zinc, aluminum, and silver.

12. A semiconductor package comprising:
a package substrate;
an interposer substrate on the package substrate;
a first semiconductor chip on the interposer substrate;
a molding layer surrounding the first semiconductor chip on the interposer substrate; and
a metal layer on an upper surface of the molding layer and on the first semiconductor chip,
wherein the metal layer includes a shape memory alloy that is configured to reversibly change between crystalline phases according to a temperature of the metal layer, and
the metal layer has a crystalline phase change temperature between 70° C. and 110° C.

13. The semiconductor package of claim 12, further comprising second semiconductor chips stacked on the upper surface of the first semiconductor chip,
wherein each of the second semiconductor chips includes a penetration via penetrating through an inside of a respective second semiconductor chip,
the second semiconductor chips are electrically connected to each other through the penetration vias,
an upper surface of an uppermost second semiconductor chip among the second semiconductor chips is coplanar with the upper surface of the molding layer, and
the metal layer is on an upper surface of the uppermost second semiconductor chip.

14. The semiconductor package of claim 12, further comprising an adhesive layer interposed between the first semiconductor chip and the metal layer, and between the molding layer and the metal layer.

15. The semiconductor package of claim 12, wherein the metal layer is configured such that when it is cooled to a temperature equal to or lower than the crystalline phase change temperature, the metal layer is changed from an austenite phase to a martensite phase, and
such that when the metal layer is heated to a temperature equal to or higher than the crystalline phase change temperature, the metal layer is recovered from the martensite phase to the austenite phase.

16. The semiconductor package of claim 12, wherein the metal layer extends from the upper surface of the molding layer to at least partially surround sides of the molding layer.

17. A method for manufacturing a semiconductor package, the method comprising:
providing an interposer substrate;
mounting a first semiconductor chip and a chip stack on an upper surface of the interposer substrate;
forming a molding layer surrounding the first semiconductor chip and the chip stack on the upper surface of the interposer substrate;
manufacturing a stack package by forming a metal layer on an upper surface of the molding layer, an upper surface of the chip stack, and an upper surface of the first semiconductor chip; and
mounting the stack package on a package substrate,
wherein the metal layer includes a shape memory alloy configured to reversibly change a shape thereof according to a temperature of the metal layer.

18. The method of claim 17, wherein forming the metal layer comprises forming the metal layer on the upper surface of the molding layer, the upper surface of the first semiconductor chip, and the upper surface of the chip stack in a physical vapor deposition (PVD) process.

19. The method of claim 17, wherein forming the metal layer comprises attaching the metal layer onto the upper surface of the molding layer, the upper surface of the first semiconductor chip, and the upper surface of the chip stack by using an adhesive layer provided on a lower surface of the metal layer.

20. The method of claim 17, wherein:
the metal layer has a first shape at a first temperature lower than a crystalline phase change temperature;
the metal layer has a second shape different from the first shape at a second temperature higher than the crystalline phase change temperature;
the metal layer is configured such that when it is heated from the first temperature to the second temperature, the metal layer recovers the second shape,
forming the metal layer is performed at the first temperature, and
mounting the stack package is performed at the second temperature.
